(19) United States
(12) Patent Application Publication
(10) Pub. No.: US 2005/0230005 A1
(43) Pub. Date: Oct. 20, 2005

(54) Test pad for reducing die sawing damage

(75) Inventors: Ming-Shuoh Liang, Kaohsiung City (TW); Tze-Liang Lee, Hsinchu (TW); Shih-Chang Chen, Hsin-Chu (TW)

Correspondence Address: DUANE MORRIS, LLP;IP DEPARTMENT, ONE LIBERTY PLACE, PHILADELPHIA, PA, 19103-7396, US

(73) Assignee: Taiwan Semiconductor Manufacturing Co., Ltd.

(21) Appl. No.: 11/141,863

(22) Filed: Jun. 1, 2005

Related U.S. Application Data
(63) Continuation-in-part of application No. 10/603,261, filed on Jun. 25, 2003.

(51) Int. Cl. H01L 29/02

(52) U.S. Cl. 148/33.3

(57) ABSTRACT

A test pad comprises a plurality of metal lines formed in a plurality of metal layers disposed over a wafer or substrate. The plurality of metal lines form a slotted pad member that includes at least one elongated main pad section, at least one side pad section, and a plurality of metal filled vias connecting the lines in the metal layers. The number of vias provided in the central area of the pad may be reduced in number or not provided at all.

### RELATED APPLICATIONS

This application is a continuation-in-part of U.S. application Ser. No. 10/603,261 filed on Jun. 25, 2003, the entire disclosure of which is incorporated herein by reference.

### FIELD OF INVENTION

The invention relates to semiductor devices. More particularly, the invention relates to test pads for reducing die sawing damage.

### BACKGROUND OF THE INVENTION

Semiconductor devices or circuits are typically fabricated on a large semiconductor wafers in multiple passes. Over a fabrication time period, the semiconductor devices or circuits will be fabricated with multiple layers. Once the fabrication process is complete, the individual semiconductor devices or circuits must be separated from each other by sawing the wafer into individual dies along scribe lines (saw streets) which separate the devices or circuits. Each of the dies will typically include a semiconductor device or circuit.

Referring now to FIG. 1, as will be familiar to those of ordinary skill in the semiconductor fabrication arts, a danger in the separation process is that cracks and other imperfections can develop during the separation process, often as a result of sawing. Pads 10, which are connection points to provide electrical connectivity with the die 2, are often a point where such failures manifest.

Many current pad designs of test keys on scribe lines for copper/low-resistance (Cu/low-K) designs enlarge the chipping area when sawing the wafer along the scribe lines.

Chipping often occurs along the die edges, resulting in poor reliability or even complete damage to the circuitry on the die.

### SUMMARY OF THE INVENTION

A test pad is disclosed for a wafer or substrate. In one embodiment the test pad comprises a plurality of metal lines formed in a plurality of metal layers disposed over a wafer or substrate, the plurality of metal lines forming a slotted pad member.

In another embodiment, the test pad comprises a plurality of metal lines formed in a plurality of metal layers disposed over a wafer or substrate, the plurality of metal lines forming a slotted pad member, the slotted pad member including at least one elongated main pad section, at least one side pad section, and a plurality of metal filled vias connecting the lines in the metal layers wherein a central area of the pad has a reduced number of the vias.

In a further embodiment, the test pad comprises a plurality of metal lines formed in a plurality of metal layers disposed over a wafer or substrate, the plurality of metal lines forming a slotted pad member, the slotted pad member including at least one elongated main pad section, at least one side pad section, and a plurality of metal filled vias connecting the lines in the metal layers, except in a central area of the pad.

### BRIEF DESCRIPTION OF THE DRAWINGS

FIG. 1 is a plan view of a wafer showing one of the die and saw streets.

FIG. 2A is a sectional view through line 2A-2A of FIG. 2B of an embodiment of a test pad of the invention.

FIG. 2B is a sectional view through line 2B-2B of the test pad of FIG. 2A.

FIG. 3A is a sectional view through line 3A-3A of FIG. 3B of an alternate embodiment of a test pad of the invention.

FIG. 3B is a sectional view through line 3B-3B of the test pad of FIG. 3A.

FIG. 4A is a sectional view through line 4A-4A of FIG. 4B of another embodiment of a test pad of invention.

FIG. 4B is a sectional view through line 4B-4B of the test pad of FIG. 4A.

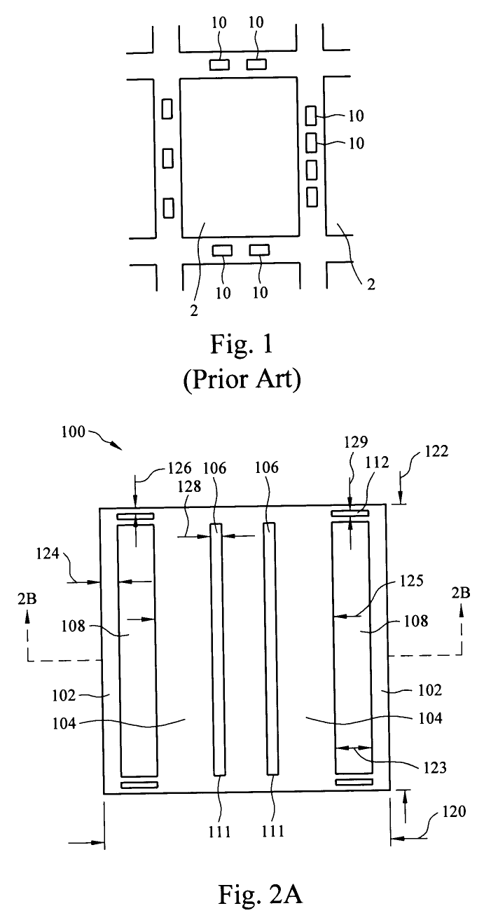

### DETAILED DESCRIPTION OF THE INVENTION

The invention relates to a test key pad for wafer acceptance testing (WAT) and other applications. The test key pad of the invention is intended for use in the saw streets of semiconductor wafers and other substrates. The test key pad of the invention may also be used in other areas of a wafer or substrate. The test key pad of the invention comprises a slotted pad area, a smaller number of metal filled vias in the center of the pad, and buffer areas where pad material has been omitted. These features reduce the stiffness of the pad while still maintaining sufficient area for contact with a test probe. When used in the saw street of a semiconductor wafer, the test key pad of the invention reduces stress and therefore, significantly eliminates crack penetration into adjacent wafer dies while sawing along the scribe lines during the wafer die separation process.

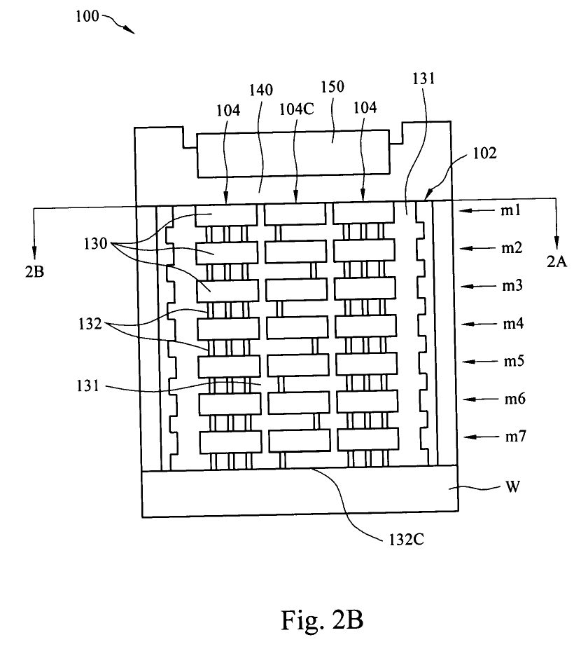

FIGS. 2A and 2B respectively show sectional views of an embodiment of the test key pad of the invention, denoted by numeral 100. As shown in the sectional view of FIG. 2A, the test key pad 100 is slotted to form thin, elongated side pad sections 102 and a plurality of elongated main pad sections 104 disposed between the side pad sections 102. An elongated, slot-like inner buffer area (inner slot) 106 is disposed between adjacent main pad sections 102, and an elongated, slot-like, outer buffer area (outer slot) 108 is disposed between each outermost main pad section 104 and an adjacent side pad section 102. Pairs of web-like pad sections 110 connect the side pad sections 102 to adjacent ones of the outermost main pad sections 104. Web-like pad sections 111 connect adjacent main pad sections 104. The area between each pair of web-like pad sections 110 forms a transverse, slot-like buffer area (transverse slot) 112.

The thin elongated side pad sections 102 define the boundaries of the pad area and confine any cracks induced by die sawing. The web-like pad sections 110 and transverse buffer areas 112 operate to weaken the entire pad structure so that it can be more easily diced during die sawing. The transverse buffer areas 112 also prevent the forces generated during die sawing from being transferred outside the pad area. The outer buffer areas 108 operate to prevent outward propagation of cracks induced by dicing the main pad sections 104.

In one embodiment, the pad 100 may have a width 120 of 65 um and a length 122 of about 65 urn which allows it to be used in a 80 um wide saw street. In such an embodiment, the outer slots 108 may each have a width 123 of about 7.5 um, the side pad sections 102 may each have a width 124 of about 5 um, the main pad sections 104 may have a combined width 125 of about 40 um, the web-like pad sections 110 may have a width 126 of about 2 um, the inner slots 106 may each have a width 128 of about 2 um, and the transverse slots 112 may each have a width 129 of about 0.5 um.

As shown in the sectional view of FIG. 2B, the pad sections of the test key pad 100 may be formed on a semiconductor wafer W by a plurality of metal lines 130 in a plurality of metal layers (e.g., M1-M7). The metal lines 130 are separated from one another by dielectric material 131, which forms the earlier described buffer areas or slots. Metal filled vias 132 vertically connect the metal lines 130 in the metal layers M1-M7. The metal lines 130 forming the generally centermost main pad section (denoted by reference numeral 104c in FIG. 2B) are vertically connected by a fewer number of vias (denoted by reference numeral 132c in FIG. 2B) than the metal lines 130 forming the outermost main pad sections, to reduce the stiffness of the generally centermost main pad section 104c, relative to the outermost main pad sections 104. The stiffness of the generally centermost main pad section 104c, relative to the outermost main pad sections 104 may also be reduced by staggering the vias 132c connecting the metal lines 130 forming the generally centermost main pad section 104c so that vias 132c connecting adjacent metal lines 130 are not aligned or directly over one another. A layer 140 of dielectric material is disposed on the top metal layer M1. In one embodiment, the layer 140 of dielectric material may be undoped silicate glass (USG). A metal contact pad member 150 is disposed on the layer 140 of dielectric material, and forms an upper portion of the test key pad 100. The contact pad member 150 is typically not slotted and may be electrically connected to the metal lines 130 in the top metal layer M1 by metal filled vias (not shown). In one embodiment, the contact pad member 150 may be made of aluminum.

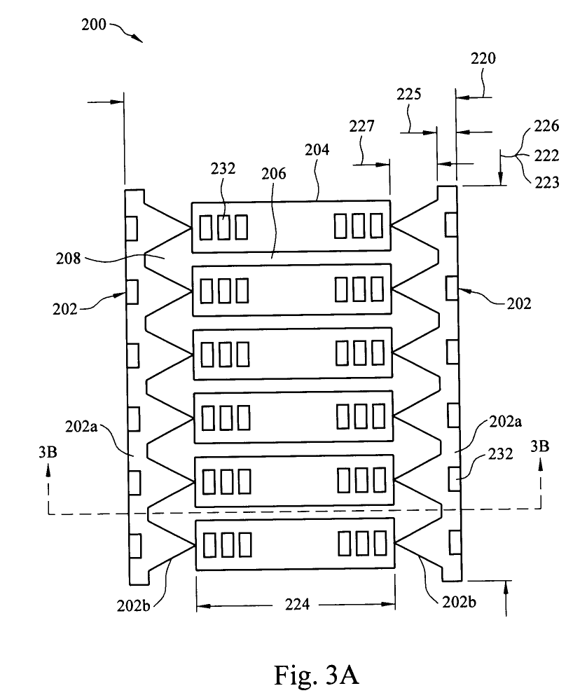

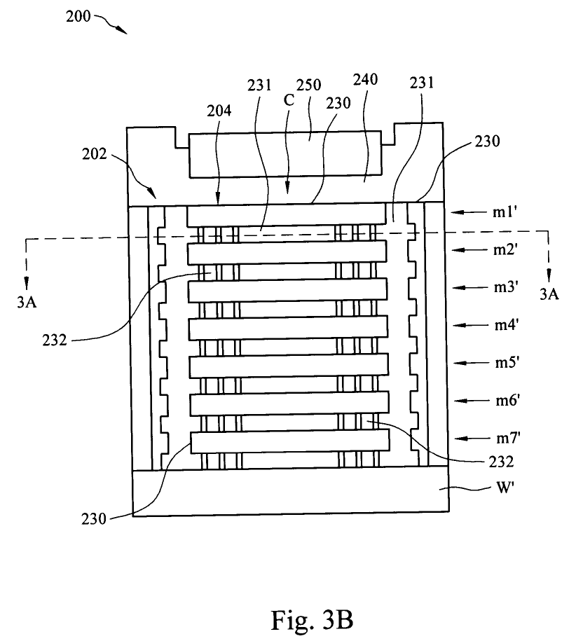

FIGS. 3A and 3B respectively show sectional views of an alternate embodiment of the test key pad of the invention, denoted by numeral 200. As shown in the sectional view of FIG. 3A, the test key pad 200 is slotted to form saw-tooth shape, side pad sections 202 each having an elongated portion 202a and inwardly facing, generally triangular-shape portions 202b, and elongated main pad sections 204 extending orthogonally to and between opposing ones of the triangular-shape portions 202b of the side pad portions 202. The ends of the main pad sections 204 may connect to the tips of the triangular-shape portions 202b of the side pad sections 202. Slot-shape inner buffer areas (inner slots) 206 are disposed between the main pad sections 204, and triangular-shape, outer buffer areas (outer slots) 208 are laterally disposed between the triangular portions 202b of the side pad sections 202 of each side pad section 202. The elongated portions 202a define the pad area and confine cracks induced by die sawing. The outer buffer areas 202b stop the forces induced by the die sawing process from extending outwardly beyond the buffer areas 202b.

In one embodiment, the pad 200 may have a width 220 of about 65 um and a length 222 of about 65 um which allows it to be used in a 80 um wide saw street. In such an embodiment, the main pad sections 204 may have a combined width 223 of about 65 um and each main pad section may have a length 224 of about 45 um. The base 202a of each side pad section 202 may have a width 225 of about 4 um and a length 226 of about 65 um. The teeth 202b of each side pad section 202 may have a height 227 of about 6 um.

As shown in the sectional view of FIG. 3B, the pad sections of the test key pad 200 may be formed on a semiconductor wafer W′ by a plurality of metal lines 230 in a plurality of metal layers (e.g., M1′-M7′). The metal lines 230 are separated from one another by a dielectric material 231, which forms the buffer areas or slots. Metal filled vias 232 (also shown in FIG. 3A) vertically connect the metal lines 230 in the metal layers M1′-M7′. The stiffness of each main pad section 204 may be reduced by reducing the number of vias and/or completely omitting the vias (as shown) in the centermost area C of the metal line stack. As in the previous embodiment, a layer 240 of dielectric material, e.g., USG, is disposed on the top metal layer M1′ and a metal contact pad member 250, e.g., of aluminum, is disposed on the layer 240 of dielectric material, and forms an upper portion of the test key pad 200.

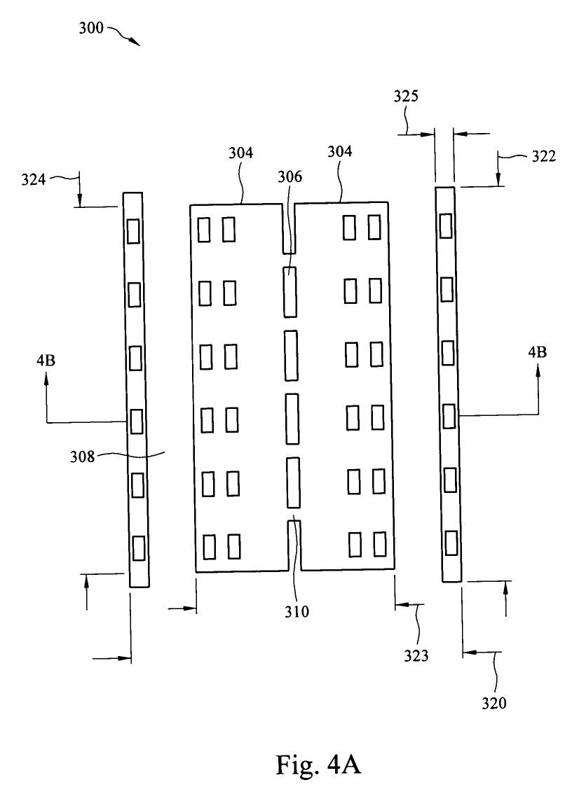

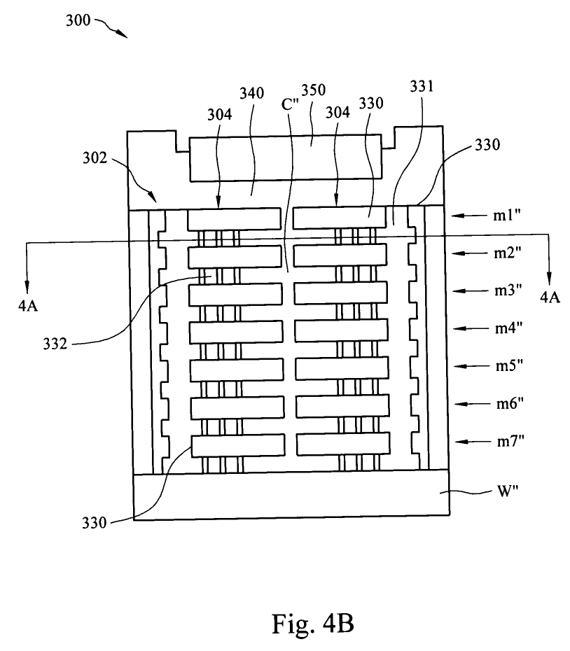

FIGS. 4A and 4B respectively show sectional views of another embodiment of the test key pad of the invention, denoted by numeral 300. As shown in the sectional view of FIG. 3A, the test key pad 300 is slotted to form thin, elongated side pad sections 302 and elongated main pad sections 304 are disposed between the side pad sections 302. A slot-like buffer area (inner slot) 306 is disposed between the main pad sections 304. A plurality of web-like pad sections 310 connect the main pad sections 304 across the inner slot 306. An elongated, slot-like, outer buffer area (outer slot) 308 is disposed between each side pad section 302 and each main pad section 304.

In one embodiment, the pad 300 may have a width 320 of about 65 um and a length 322 of about 65 um which allows it to be used in a 80 um wide saw street. In such an embodiment, the main pad sections 304 may have a combined width 323 of about 45 um and each main pad section 304 may have a length 324 of about 60 um. Each side pad section 302 may have a width 325 of about 5 um and a length of about 65 um.

As shown in the sectional view of FIG. 4B, the pad sections of the test key pad 300 may be formed on a semiconductor wafer W″ by a plurality of metal lines 330 in a plurality of metal layers (e.g., M1″-M7″). The metal lines 330 are separated from one another by a dielectric material 331, which forms the buffer areas or slots. Metal filled vias 332 vertically connect the metal lines 330 in the metal layers M1″-M7″. The stiffness of each main pad section 304 may be reduced by reducing the number of vias and/or completely omitting the vias along the marginal innermost areas the metal line stacks forming the centermost area C′ of the pad 300. Similar to the embodiment shown in FIGS. 2A and 2B, a layer 340 of dielectric material, e.g., USG, is disposed on the top metal layer M1″ and a metal contact pad member 350, e.g., of aluminum, is disposed on the layer 340 of dielectric material, and forms an upper portion of the test key pad 300.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

1. A test pad for a wafer or substrate, comprising a plurality of metal lines formed in a plurality of metal layers disposed over a wafer or substrate, the plurality of metal lines forming a slotted pad member.

2. The test pad according to claim 1, wherein the slotted pad member includes elongated pad sections.

3. The test pad according to claim 2, wherein some of the pad sections are connected to one another.

4. The test pad according to claim 1, wherein the slotted pad member includes at least one elongated main pad section.

5. The test pad according to claim 4, wherein the slotted pad member further includes at least one elongated side pad section.

6. The test pad according to claim 5, wherein the slotted pad member further includes at least one web-like pad section connecting the at least one elongated side pad section to the at least one elongated main pad section.

7. The test pad according to claim 5, wherein the slotted pad member further includes at least one web-like pad section connecting the at least one elongated main pad section to a second elongated main pad section.

8. The test pad according to claim 5, wherein the at least one elongated side pad section includes at least one tri-angular-shape portion connecting the at least one elongated side pad section to the at least one elongated main pad section.

9. The test pad according to claim 1, wherein the slotted pad member further includes at least one elongated side pad section.

10. The test pad according to claim 9, wherein the at least one elongated side pad section includes at least one tri-angular-shape portion.

11. The test pad according to claim 9, wherein the at least one elongated side pad section has a saw-tooth shape.

12. The test pad according to claim 1, wherein the slotted pad member includes at least one web-like pad section.

13. The test pad according to claim 1, wherein the test pad is formed on a scribe line.

14. The test pad according to claim 1, further comprising a plurality of metal filled vias connecting the lines in the metal layers wherein a central area of the pad has a reduced number of the vias.

15. The test pad according to claim 14, wherein the vias in the central area of the pad are not vertically aligned with one another.

16. The test pad according to claim 1, further comprising a plurality of metal filled vias connecting the lines in the metal layers, except in a central area of the pad.

17. The test pad according to claim 1, wherein the test pad comprises a wafer acceptance testing pad.

18. A test pad for a wafer or substrate, comprising a plurality of metal lines formed in a plurality of metal layers disposed over a wafer or substrate, the plurality of metal lines forming a slotted pad member, the slotted pad member including at least one elongated main pad section, at least one side pad section, and a plurality of metal filled vias connecting the lines in the metal layers wherein a central area of the pad has a reduced number of the vias.

19. The test pad according to claim 18, wherein the vias in the central area of the pad are not vertically aligned with one another.

20. A test pad for a wafer or substrate, comprising a plurality of metal lines formed in a plurality of metal layers disposed over a wafer or substrate, the plurality of metal lines forming a slotted pad member, the slotted pad member including at least one elongated main pad section, at least one side pad section, and a plurality of metal filled vias connecting the lines in the metal layers, except in a central area of the pad.
